(19) United States
(12) Patent Application Publication
(10) Pub. No.: US 2006/0083096 A1
(43) Pub. Date: Apr. 20, 2006

(54) Semiconductor memory device and package thereof, and memory card using the same

(76) Inventor: Joong Seob Yang, Seongnam-Shi (KR)

Correspondence Address: MARSHALL, GERSTEIN & BORUN LLP, 233 S. WACKER DRIVE, SUITE 6300, SEARS TOWER, CHICAGO, IL, 60606, US

(21) Appl. No.: 11/010,664

(22) Filed: Dec. 13, 2004

(30) Foreign Application Priority Data
Oct. 5, 2004 (KR) 2004-78954

(51) Int. Cl. G11C 8/00

(52) U.S. Cl. 365/230.03

(57) ABSTRACT

Disclosed herein are a semiconductor memory device and package thereof, and a memory card using the same. The semiconductor memory device may include a memory cell array in which a plurality of memory cells that share a word line constitutes a page. The same row address signal is inputted to two or more memory chips including a row decoder for selecting the page, so that predetermined pages of the two or more memory chips are selected at the same time. If the semiconductor memory device is packaged or applied to the memory card, the size of the page can be significantly reduced. Also, since data is alternately loaded into the memory chips or data of the memory chips is alternately outputted, an overall program and read speed can be thus improved. Therefore, the performance of the semiconductor memory device can be improved.

### FIELD OF THE TECHNOLOGY

This disclosure relates generally to a semiconductor memory device, and, more specifically, to a semiconductor memory device in which the operating speed can be enhanced, while increasing the size of a page in the semiconductor memory device such as a flash memory or DRAM.

### BACKGROUND

In writing data in a cell or reading data from a cell, the unit that the write operation or the read operation is executed once is called “page”. In the case of a NAND type flash memory device, the page consists of a plurality of cells, which share a single word line. Recently, the unit of the page is expanded from 512 byte to 2 Kbyte, so that the amount of data processed per hour is increased.

Meanwhile, what data is loaded into a page buffer in a data transfer procedure between a cell and the outside is called “data loading”, and what the page buffer outputs data to the outside is called “data output”. In this case, time specs of the data loading and the data output are expressed into tWC and tRC, respectively. If data is sequentially loaded into a page of 2 Kbyte unit, however, a total loading time is inevitably longer than that in existing 512 byte. In response to this, the tWC spec is made fast, e.g., from 50 ns to 30 ns. If it is desired that the tWC spec is made faster, the size of the page needs to be extended from 2 Kbyte to 4 Kbyte, etc.

In existing technology, however, as the number of cells sharing the word line increases, the structure of the chip becomes excessively large in one direction. It is thus difficult to design such a spec. Furthermore, since the loading time of data increases, tWC must be reduced from 30 ns to 15 to 20 ns so as to reduce lowering in efficiency accordingly. Therefore, design load become heavy accordingly. In addition, as power consumption of the chip increases, design load for managing it become heavy.

### SUMMARY

In one aspect, the invention is directed to a semiconductor memory device in which a plurality of memory cells that share a word line constitutes one page and a plurality of pages constitutes a memory cell array, wherein the semiconductor memory device may include a row decoder for selecting a predetermined page according to a row address signal, thus constituting memory chips, wherein two or more memory chips receive one row address signal as a common input and predetermined pages of the two or more memory chips are selected at the same time.

The two or more memory chips may input or output data through the same I/O pin.

Each of the two or more memory chips may include a page buffer block for storing program data of the selected page or read data of the selected page, an I/O buffer for outputting the data from the page buffer block to the outside or storing data from the outside in the page buffer block, and a column decoder for connecting the page buffer block and the I/O buffer.

The two or more memory chips may be alternately selected depending on a low-order byte of the column address signal and a control signal to alternately perform data I/O operations.

The two or more memory chips may be alternately selected according to a combination of a control signal and a modified control signal whose period is extended, thus alternately performing data I/O operations.

The two or more memory chips may receive the same command and perform all commands at the same time, wherein a data I/O operation is alternately executed.

The I/O buffers of the two or more memory chips may be synchronized to the falling edge or the rising edge of a write enable signal or a read enable signal so that the I/O buffers are not enabled at the same time when inputting/outputting data.

The control signal may be generated by a circuit included in the memory chip.

In another aspect, the invention is directed to a semiconductor memory device, which may include a memory cell array including a plurality of pages, wherein a plurality of memory cells that share a word line constitutes one page, a row decoder for selecting a predetermined page of the memory cell array according to a row address signal, a page buffer block for storing program data of the selected page or read data of the selected page, an I/O buffer for outputting data from the page buffer block to the outside or storing data from the outside in the page buffer block, and a column decoder for connecting the page buffer block and the I/O buffer, whereby one memory chip is constituted, wherein two or more memory cell arrays receive one row address signal as a common input and predetermined pages of the two or more memory cell arrays are thus selected at the same time, and data I/O operations of the two or more memory cell arrays are alternately performed according to a low-order byte of a column address signal and a control signal.

In a further aspect, the invention is directed to a package of a semiconductor memory device in which two or more memory chips are electrically connected, wherein two or more memory chips receive one row address signal as a common input and predetermined pages of the two or more memory chips are thus selected at the same time, and data I/O operations of the two or more memory chips are alternately performed according to a low-order byte of a column address signal and a control signal.

The two or more memory chips may include an I/O pin, an address pin and a control pin commonly connected.

In yet another aspect, the invention is directed to a memory card having a controller for controlling a memory chip and a memory chip, wherein two or more memory chips receive one row address signal as a common input and predetermined pages of the two or more memory chips are thus selected at the same time, and data I/O operations of the two or more memory chips are alternately performed according to a low-order byte of a column address signal and a control signal.

The two or more memory chips may receive the same command at the same time to perform all command, wherein the data I/O operations are alternately performed.

### BRIEF DESCRIPTION OF THE DRAWINGS

FIG. 1 is a circuit diagram illustrating the configuration of a semiconductor memory device;

FIG. 2 shows the configuration of a memory cell array in the semiconductor memory device;

FIG. 3 is a schematic view for explaining a column address allocation method in the semiconductor memory device;

FIG. 4 is a timing diagram for explaining the data loading operation of the semiconductor memory device;

FIG. 5 is a timing diagram for explaining the data output operation of the semiconductor memory device;

FIG. 6 is a timing diagram for explaining the data output operation in the bust mode; and

FIGS. 7A and 7B are exemplary circuits for data output in the bust mode.

### DETAILED DESCRIPTION

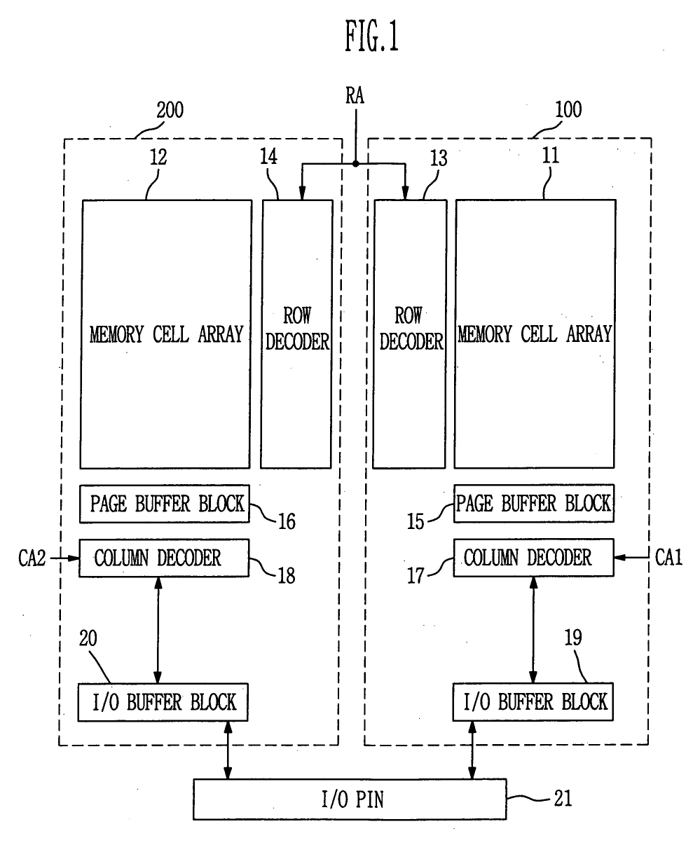

FIG. 1 is a circuit diagram illustrating the configuration of a semiconductor memory device. In FIG. 1, there is shown the construction of the NAND type flash memory device in which row decoders 13 and 14 of first and second memory chip 100 and 200 receive the same row address signal RA as an input and select a predetermined page of each of memory cell arrays 11 and 12.

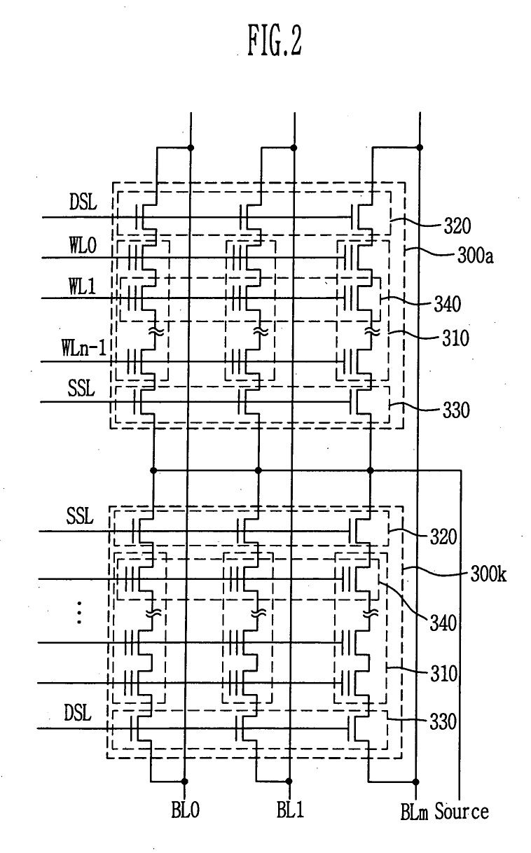

FIG. 2 shows the configuration of a memory cell array in the semiconductor memory device. Although it has been described that the two memory chips receive the same row address signal as an input, the disclosed device is not limited thereto, but can be applied to a case where two or more memory chips select corresponding pages at the same time according to the same row address signal. Meanwhile, one memory chip is designed so that the two memory cell arrays share a single row decoder, and it can be designed so that the same row address signal is commonly inputted to the two or more memory cell arrays designed thus.

The first memory chip 100 includes a memory cell array 11, a row decoder 13, a page buffer block 15, a column decoder 17 and an I/O buffer 19. The second memory chip 200 also includes a memory cell array 12, a row decoder 14, a page buffer block 16, a column decoder 18 and an I/O buffer block 20. The row decoders 13 and 14 of the first and second memory chips 100 and 200 receive the row address signal RA as a common input to select predetermined pages of the memory cell arrays 11 and 12 at the same time. The column decoders 17 and 18 receive different column address signals CA1 and CA2 as an input, but share the same I/O pin 21.

The first and second memory cell arrays 11 and 12 include a plurality of cell blocks 300a to 300k, respectively. One of the cell blocks 300a to 300k includes a plurality of cell strings 310 to which a plurality of cells are connected serially, a plurality of bit lines BL, a plurality of word lines WL, drain select transistors 320 connected between the cell strings 310 and the bit lines BL, and source select transistors 330 connected between the cell strings 310 and a common source line. Meanwhile, the plurality of the memory cells sharing a single word line constitutes a page 340. All the cells share a P well. Furthermore, the drain select transistors 320 share a drain select line DSL, and the source select transistors 330 share a source select line SSL.

The row decoders 13 and 14 select predetermined pages of predetermined cell blocks, respectively, which constitute the first and second memory cell arrays 11 and 12 for a predetermined operation according to the same row address signal RA. Each of the row decoders 13 and 14 applies a predetermined voltage for a predetermined operation, for example, a program or read operation to a selected page.

Meanwhile, the page buffer blocks 15 and 16 serve to store a program data of a selected page or a read data of a selected page. The column decoders 17 and 18 connect the page buffer blocks 15 and 16 and the I/O buffers 19 and 20, respectively, according to the different column address signals CA1 and CA2, and transmit the program data or the read data.

In the semiconductor memory device constructed above, in the case of the program operation, data inputted through the I/O pin 21 and the I/O buffers 19 and 20 is alternately stored in the page buffer blocks 15 and 16 by the column decoders 17 and 18. If predetermined pages of the first and second memory cell arrays 11 and 12 are selected by the row decoder 13 and 14, respectively, the data stored in the page buffer blocks 15 and 16 is programmed into the selected pages.

In the case of the read operation, predetermined pages of the first and second memory cell arrays 11 and 12 are selected by the row decoders 13 and 14, respectively, data of the selected pages are stored in the page buffer blocks 15 and 16, respectively, and the data stored in the page buffer blocks 15 and 16 are then outputted to the outside through the I/O buffers 19 and 20 and the I/O pin 21 by means of the column decoders 17 and 18.

Meanwhile, in the semiconductor memory device, all commands are inputted to the respective memory chips at the same time. Therefore, all operations are basically executed at the same time. However, the data loading operation for program and the data output operation depending on the read are alternately executed by the first and second memory chips 100 and 200. For example, after the first memory chip 100 is loaded with data, the second memory chip 200 can be loaded with data. This can be performed as the column address signals CA1 and CA2 received from the outside are alternately inputted to the first and second memory chips 11 and 12. Such selection of the memory chip is carried out by an external column address, which is expanded when two or more memory chips are bound and packaged.

FIG. 3 is a schematic view for explaining a column address allocation method in the semiconductor memory device. FIG. 3 is for explaining the column address allocation method in the interleaving mode.

Which memory chip will be selected is determined by a combination of low-order bytes of a column address. This refers to that the respective memory chips are sequentially allocated with addresses. For example, in the case of the semiconductor memory device having the above-described first and second memory chips, column addresses are allocated to the first and second memory chips in the interleaving mode in which the addresses are sequentially allocated to the first and second memory chips, like a 0^{th} address of the first memory chip, a 0^{th} address of the second memory chip, a 1^{st} address of the first memory chip, a 1^{st} address of the second memory chips and so on.

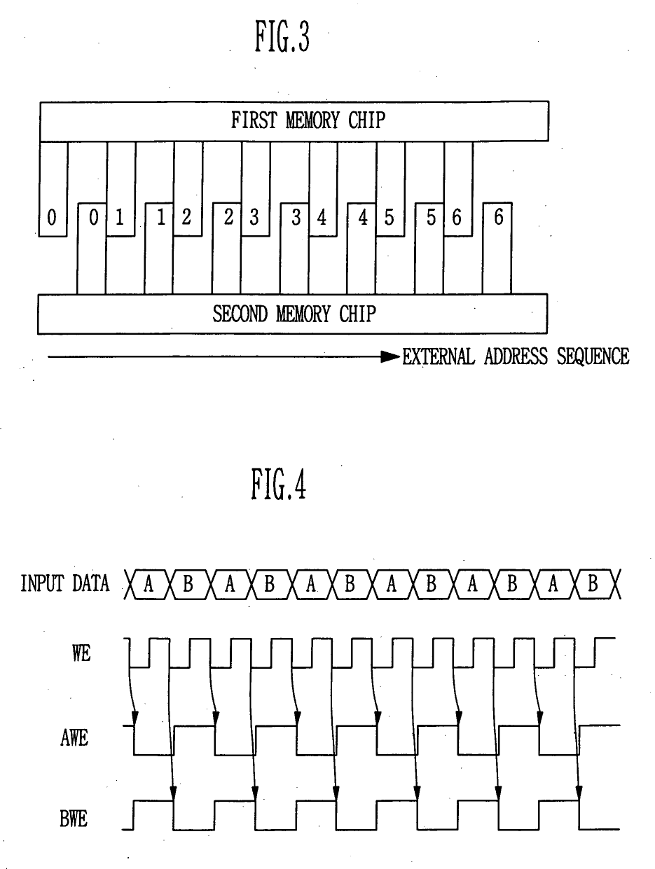

FIG. 4 is a timing diagram for explaining the data loading operation of the semiconductor memory device.

As described above, which memory chip will be programmed with data is determined through a combination of low-order bytes of the column address. That is, a signal for program into a given memory chip is generated by combining the lowest column address and an external write enable signal WE. For example, a case where the first memory chip is first selected will be described as follows.

First data A, which will be programmed into the first memory chip, and second data B, which will be programmed into the second memory chip, are alternately inputted. An internal write enable signal AWE of the first memory chip is synchronized at the falling edge of one clock of the external write enable signal WE, and the first data A is loaded into the first memory chips. On the contrary, an internal write enable signal BWE of the second memory chip is synchronized at the falling edge of a clock of a next cycle of the external write enable signal WE, and the second data B is loaded into the second memory chip. That is, the program data are sequentially loaded into the first and second memory chips every falling edges of the external write enable signal WE.

Meanwhile, the case has been described where the write enable signal of the memory chip is synchronized at the falling edge of the external write enable signal WE and the program data is programmed into the memory chip. It is, however, to be noted that a case where the memory chip is synchronized at the rising edge of the external write enable signal WE and the program data is programmed into the memory chip, is possible. In this program operation, when external data is inputted twice, data is inputted to the first and second memory chip, respectively, actually only once. Thus, the data input time can be 2 times. Accordingly, the data input from the outside can be performed twice faster than that of each unit chip.

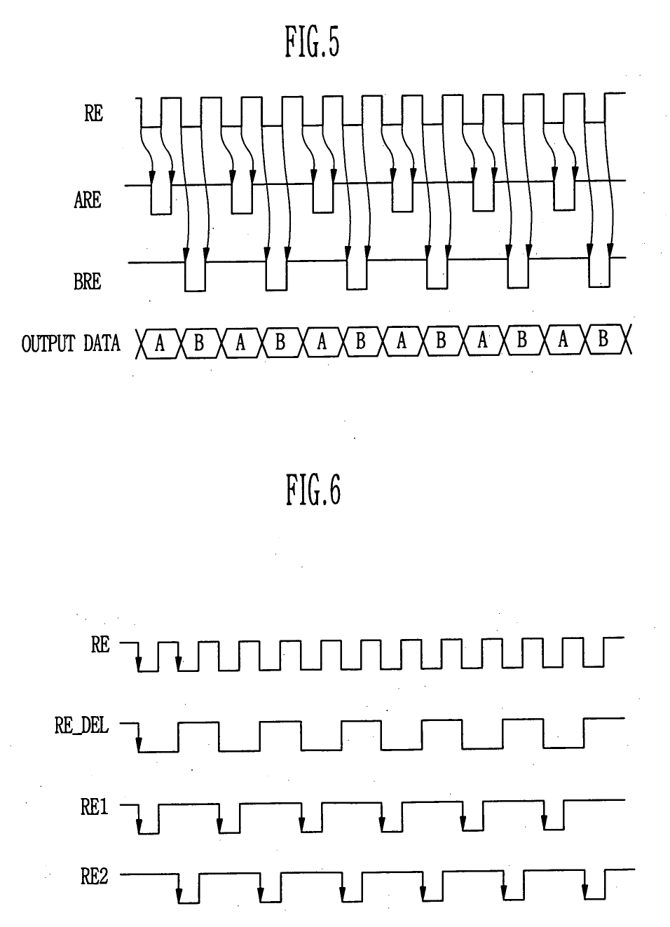

FIG. 5 is a timing diagram for explaining the data output operation of the semiconductor memory device.

As described above, Data of which memory chip will be read is determined by a combination of low-order bytes of the column address. That is, a signal for reading data of a given memory chip is generated by combining the lowest column address and an external read enable signal RE. For example, an internal read enable signal ARE of the first memory chip is synchronized in a LOW period of the external read enable signal RE and the first data A of the first memory chip is thus outputted. On the contrary, an internal read enable signal BRE of the second memory chip is synchronized in a LOW period of a next clock of the external read enable signal RE and the second data B of the second memory chip is thus outputted.

That is, every LOW period of the external read enable signal RE, the first data of the first memory chip and the second data of the second memory chip are repeatedly outputted. Meanwhile, a case where the read enable signal of the memory chip is synchronized in the LOW period of the external read enable signal RE and the data of the memory chip is outputted has been described. It is, however, to be noted that a case where the read enable signal of the memory chip is synchronized in the HIGH period of the external read enable signal RE and the data of the memory chip is outputted is possible. In this operation, however, if the output buffer of the first memory chip and the output buffer of the second memory chip are driven at the same time, a case where different data compete with each other can occur. Accordingly, excessive current consumption and data distortion can be generated. It is thus required that the time when the output buffers are driven be not overlapped.

FIG. 6 is a timing diagram for explaining the data output operation in the bust mode. FIG. 6 is shown to explain a method in which respective memory chips are alternately selected in the case where a flash memory device, DRAM, etc. output data in the bust mode.

If the memory chip is driven in the bust mode where a large amount of consecutive data is inputted/outputted, a column address signal may not be applied from the outside. In the bust mode, the memory chip operates according to the write enable signal WE in the program operation, and operates according to the read enable signal RE in the read operation. In this case, two or more memory chips are alternately selected. Each of the memory chips alternately receives the write enable signal WE or the read enable signal RE. In a period where the other memory chip operates, a signal is disregarded and an internal operation is not performed. Then, a method in which the memory chips are alternately selected in the bust mode will now be described.

An address in the case where a specific start address is not inputted is a first address by default. The first address of the first memory chip is first selected. Accordingly, the second memory chip disregards the first write enable signal WE or the read enable signal RE and operates beginning with the second write enable signal WE or the read enable signal RE. If the second memory chip operates in the bust mode beginning with a given row address, it inputs a row address when inputting a command. In this time, one of the first memory chip and the second memory chip whose address is coincident with the first address is determined depending on whether the lowest address of the row address is 0 or 1. Next, a method in which the write enable signal WE or a next read enable signal RE is synchronized is the same as those described above. The memory chip whose address is coincident with the first address is first selected and a plurality of memory chips is then alternately selected.

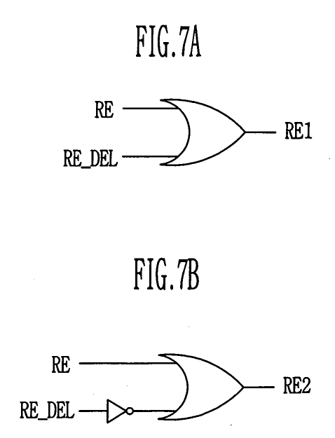

In a semiconductor device having two memory chips, exemplary circuits suitable for the memory chips by modifying the read enable signal RE are shown in FIGS. 7A and 7B. With the period of the read enable signal RE being made twice, a delay read enable signal RE_DEL is generated. An OR gate receives the read enable signal RE and the delay read enable signal RE_DEL to generate a first read enable signal RE1 necessary for each of the memory chips. Furthermore, an OR gate receives the read enable signal RE and an inverted signal of the delay read enable signal RE_DEL which is inverted by the inverter to generate a second read enable signal RE2. A circuit that generates the first read address signal RE1 is constructed in the memory chip whose address is coincident with the first address, i.e., the memory chip where the bust begins. A circuit that generates the second read address signal RE2 is constructed in the opposite side. The same is true of the write enable signal WE.

Meanwhile, two or more memory chips can be formed in at least one package, and two or more memory chips can receive a single row address signal as a common input and predetermined pages of the two or more memory chips are selected at the same time.

In a memory card having a controller for controlling memory chips, two or more memory chips can receive a single row address signal as a common input and predetermined pages of two or more memory chips are selected at the same time. Furthermore, the data I/O operations of the two or more memory chips can be alternately executed depending on the low-order byte of the column address signal and the control signal.

As described above, a semiconductor memory device is constructed in which two or more memory chips receive the same row address signal and share the same I/O pin, and predetermined pages of the memory chips are alternately selected according to the low-order byte of the column address signal or the control signal. The semiconductor memory device is packaged. It is thus possible to significantly increase the size of a page. By sequentially loading data to the respective memory chips or sequentially outputting data of the memory chips, the program and read speed can be improved. Accordingly, the disclosed device can enhance the performance of the semiconductor memory device.

Although certain examples of methods and apparatus constructed in accordance with the teachings of the invention have been described herein, the scope of coverage of this patent is not limited thereto. On the contrary, this patent covers all embodiments of the teachings of the invention fairly falling within the scope of the appended claims either literally or under the doctrine of equivalents.

What is claimed is:

1. A semiconductor memory device in which a plurality of memory cells that share a word line constitutes one page and a plurality of pages constitutes a memory cell array, wherein the semiconductor memory device includes a row decoder for selecting a predetermined page according to a row address signal, thus constituting memory chips,
wherein two or more memory chips receive one row address signal as a common input and predetermined pages of the two or more memory chips are selected at the same time.

2. The semiconductor memory device as claimed in claim 1, wherein the two or more memory chips input or output data through the same I/O pin.

3. The semiconductor memory device as claimed in claim 1, wherein each of the two or more memory chips comprises:
a page buffer block for storing program data of the selected page or read data of the selected page;
an I/O buffer for outputting the data from the page buffer block to the outside or storing data from the outside in the page buffer block; and
a column decoder for connecting the page buffer block and the I/O buffer.

4. The semiconductor memory device as claimed in claim 1, wherein the two or more memory chips are alternately selected depending on a low-order byte of the column address signal and a control signal to alternately perform data I/O operations.

5. The semiconductor memory device as claimed in claim 4, wherein the control signal is generated by a circuit included in the memory chip.

6. The semiconductor memory device as claimed in claim 1, wherein the two or more memory chips are alternately selected according to a combination of a control signal and a modified control signal whose period is extended, thus alternately performing data I/O operations.

7. The semiconductor memory device as claimed in claim 6, wherein the control signal is generated by a circuit included in the memory chip.

8. The semiconductor memory device as claimed in claim 1, wherein the two or more memory chips receive the same command and perform all commands at the same time, wherein a data I/O operation is alternately executed.

9. The semiconductor memory device as claimed in claim 1, wherein the I/O buffers of the two or more memory chips are synchronized to the falling edge or the rising edge of a write enable signal or a read enable signal so that the I/O buffers are not enabled at the same time when inputting/outputting data.

10. A semiconductor memory device, comprising:
a memory cell array including a plurality of pages, wherein a plurality of memory cells that share a word line constitutes one page;
a row decoder for selecting a predetermined page of the memory cell array according to a row address signal;
a page buffer block for storing program data of the selected page or read data of the selected page;
an I/O buffer for outputting data from the page buffer block to the outside or storing data from the outside in the page buffer block; and
a column decoder for connecting the page buffer block and the I/O buffer, whereby one memory chip is constituted,
wherein two or more memory cell arrays receive one row address signal as a common input and predetermined pages of the two or more memory cell arrays are thus selected at the same time, and
data I/O operations of the two or more memory cell arrays are alternately performed according to a low-order byte of a column address signal and a control signal.

11. A package of a semiconductor memory device in which two or more memory chips are electrically connected,
wherein two or more memory chips receive one row address signal as a common input and predetermined pages of the two or more memory chips are thus selected at the same time, and
data I/O operations of the two or more memory chips are alternately performed according to a low-order byte of a column address signal and a control signal.

12. The package as claimed in claim 11, wherein the two or more memory chips have an I/O pin, an address pin and a control pin commonly connected.

13. A memory card having a controller for controlling a memory chip and a memory chip,
wherein two or more memory chips receive one row address signal as a common input and predetermined pages of the two or more memory chips are thus selected at the same time, and
data I/O operations of the two or more memory chips are alternately performed according to a low-order byte of a column address signal and a control signal.

14. The memory card as claimed in claim 13, wherein the two or more memory chips receive the same command at the same time to perform all command, wherein the data I/O operations are alternately performed.
